(19) United States
(12) Patent Application Publication
(10) Pub. No.: US 2011/0108946 A1
(43) Pub. Date: May 12, 2011

(54) FUSE OF SEMICONDUCTOR DEVICE AND METHOD FOR FORMING THE SAME

(75) Inventor: Jin Won PARK, Seongnam (KR)

(73) Assignee: Hynix Semiconductor Inc., Icheon (KR)

(21) Appl. No.: 12/823,999

(22) Filed: Jun. 25, 2010

(30) Foreign Application Priority Data
Nov. 11, 2009 (KR) 10-2009-0108592

(51) Int. Cl. H01L 23/525; H01L 21/768

(52) U.S. Cl. 257/529; 438/601; 257/E23.15; 257/E21.592

(57) ABSTRACT

A fuse of a semiconductor device includes a fuse pattern separated by a blowing region formed on an interlayer insulating film, and a recess formed by removing a portion of the upper portion of a plurality of contacts disposed in the lower portion of the blowing region. After the fuse pattern is blown, the fuse pattern moves in the reliable environment, thereby preventing the electric short to improve yield of the semiconductor device.

### CROSS-REFERENCE TO RELATED APPLICATION

The priority of Korean patent application No. 10-2009-108592 filed on Nov. 11, 2009, the disclosure of which is hereby incorporated in its entirety by reference, is claimed.

### BACKGROUND OF THE INVENTION

The present invention relates to a semiconductor device having a fuse and a method for forming the same, and more specifically, to a fuse of a semiconductor device and a method for forming the same to improve reliability of the semiconductor device.

A semiconductor device such as a memory device and a memory merged logic (MML) includes a plurality of memory cells for storing data. If at least one memory cell of a memory array in the semiconductor device has a defect, the whole device will fail as a memory, so that the whole device is defective. That is, although there is only one defective memory cell in the memory device, the whole device is regarded as being defective and thus discarded, which decreases the yield of the device.

In order to improve the yield of the semiconductor device, a repair method is required. The repair method of the semiconductor device is performed by replacing a defective memory cell with a redundancy memory cell. In order to replace the defective memory cell with the redundancy memory cell, a fuse capable of being cut is used. Therefore, a semiconductor device includes a plurality of fuses that may be cut by a common laser. After testing the semiconductor device, the fuses are selectively cut depending on a test result.

In the repair method using the redundancy cell, each cell array includes a redundancy word line and a redundancy bit line. When a defect is generated in a specific cell, the normal word line or the normal bit line is substituted with the redundancy word line or the redundancy bit line. In the memory device, when a defective cell is found through a test after wafer processing, a corresponding circuit is activated to substitute an address corresponding to the defective cell with an address corresponding to the redundancy cell. As a result, when an address signal corresponding to the defective cell is inputted, data contained in the substituted redundancy cell corresponding to the defective cell is accessed.

Among repair methods, a widely used method is to burn a fuse with a laser beam and blow out the fuse, thereby changing an address path. Therefore, a general memory device includes a fuse unit configured to change an address path by irradiating a laser onto the fuse unit to blow out the fuse. A wire disconnected by laser irradiation is referred to as a metal fuse, and the disconnected site and its surrounding region are referred to as a fuse box.

### BRIEF SUMMARY OF THE INVENTION

Various embodiments of the invention are directed to preventing the short circuit resulting from movement of a fuse pattern when the fuse pattern is cut by a blowing process, thereby improving reliability of a semiconductor device.

According to an embodiment of the present invention, a fuse of a semiconductor device includes: a fuse pattern having a first portion and a second portion formed over an interlayer insulating film, a blowing region separation the fuse pattern into the first portion and the second portion, a plurality of contacts provided within contact holes below the blowing region, and a recess formed by partially removing an upper portion of one or more of the contacts within the contact holes.

A substrate provided below the interlayer insulating film and the contacts, wherein a lower end of each the contact contacts the substrate.

The fuse further comprises a substrate, a first conductive line formed over the substrate and below the interlayer insulating film, and a first fuse contact having an upper end and a lower end and extending through the interlayer insulating film, the upper end of the first fuse contact contacting the first portion of the fuse pattern, the lower end of the first fuse contact contacting the first conductive line.

The fuse further comprises a second conductive line formed over the substrate and below the interlayer insulating film, the second conductive line being separated from the first conductive line by an insulating layer, and a second fuse contact having an upper end and a lower end and extending through the interlayer insulating film, the upper end of the second fuse contact contacting the second portion of the fuse pattern, the lower end of the second contact fuse contacting the second conductive line.

The recess is configured to prevent the first and second portions of the fuse pattern from migrating to another location and causing a short circuit.

The fuse further comprises a substrate, a first conductive line formed over the substrate and below the interlayer insulating film, a second conductive line formed over the substrate and below the interlayer insulating film, an insulating layer provided below the interlayer insulating film and separating the first conductive line from the second conductive line, a first fuse contact having an upper end and a lower end and extending through the interlayer insulating film, the upper end of the first fuse contact contacting the first portion of the fuse pattern, the lower end of the first fuse contact contacting the first conductive line, and a second fuse contact having an upper end and lower end and extending through the interlayer insulating film, the upper end of the second fuse contact contacting the second portion of the fuse pattern, the lower end of the second contact fuse contacting the second conductive line.

According to an embodiment of the present invention, a method for forming an interlayer insulating film over a substrate, forming a plurality of contacts extending through the interlayer insulating film, each contact having an upper end and a lower end, the lower end contacting the substrate, forming a fuse pattern over the interlayer insulating film and the contacts, the fuse pattern contacting the upper end of each contact, removing a portion of the fuse pattern to form a blowing region and separating the fuse pattern into a first portion and a second portion, and removing an upper portion of one or more of the contacts to form a recess.

The method further comprises forming first and second conductive lines over the substrate, etching the interlayer insulating film to form first and second fuse contact holes exposing the first and second conductive lines, respectively, wherein the first fuse contact contacts the first conductive line and the second fuse contact contacts the second conductive line.

The first and second conductive lines are separated from each other by an insulating layer formed between the interlayer insulating film and the substrate.

The fuse contact and the contacts are formed using the same material.

The contacts are formed to be connected to the middle part of the fuse pattern.

After forming the fuse pattern, the method further comprises: forming an dielectric film over the fuse pattern, and etching a portion of the dielectric film to reduce a thickness of the insulating film to thereon and define a window, whereby the dielectric film has a less thickness at the window than at an area adjacent to the window.

The forming-the-blowing-region comprises applying a laser to window of the dielectric film and a portion of the fuse pattern underlying the window.

The forming-the recess comprises partially removing the upper portion of the contacts using the laser.

### BRIEF DESCRIPTION OF THE DRAWINGS

FIG. 1 is a plan view illustrating a fuse of a semiconductor device according to an embodiment of the present invention.

FIGS. 2A and 2B are cross-sectional views illustrating the fuse of the semiconductor device taken along an A-A′ line and a B-B′ line in FIG. 1, respectively.

FIGS. 3A to 3D are cross-sectional views illustrating a method for forming the fuse of the semiconductor device in FIG. 1 according to an embodiment of the present invention.

### DESCRIPTION OF EMBODIMENTS

Embodiments of the present invention will be described in detail with reference to the attached drawings. Wherever possible, the same reference numbers will be used throughout the drawings to refer to the same or like elements.

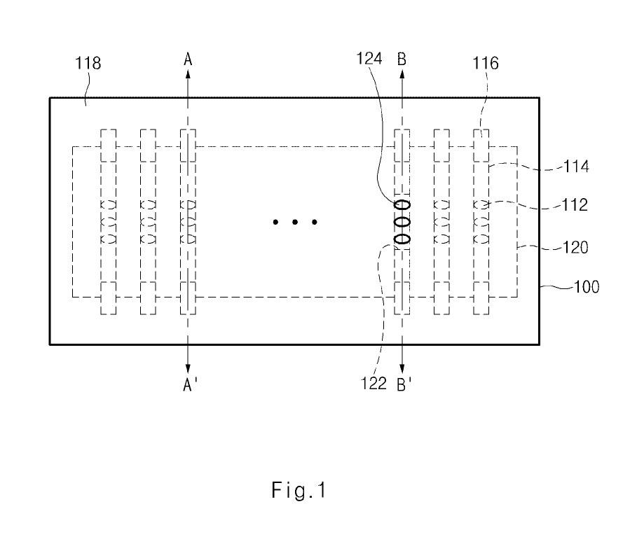

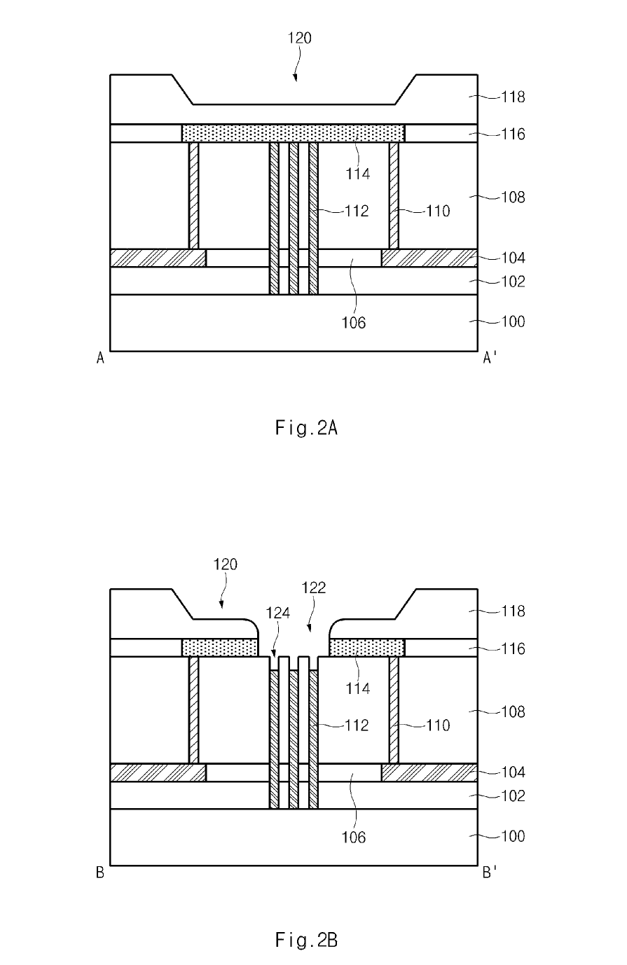

FIG. 1 is a plan view illustrating a fuse of a semiconductor device according to an embodiment of the present invention. FIGS. 2A and 2B are cross-sectional views illustrating the fuse of the semiconductor device taken along an A-A′ line and a B-B′ line in FIG. 1, respectively.

Referring to FIG. 1 and FIGS. 2A and 2B, the fuse includes a plurality of line-type fuse patterns 114 separated from each other at given intervals, a plurality of contacts 112 coupled to each other in a middle portion of the fuse pattern 114, and a dielectric film 118 including a window 120 to cover the fuse pattern 114. The contacts 112 are provided within contact holes. The fuse further includes a blowing region 122 formed when a laser is applied to a certain portion of the fuse to remove a portion of the interlayer insulating film 118 and the fuse pattern 114. The blowing region 122 separates the fuse pattern 114 into a first portion and a second portion. The laser is also used to form a recess (or recess) 124 by removing a portion of the contact 112. The recess 124 prevents the fuse pattern 114 from being easily moved in a subsequent process for testing reliability. As a result, defects such as short circuits can be prevented even when the fuse pattern 114 is blown out. The recess 124 will be described in detail with reference to FIG. 2B illustrating the cross-sectional view of the semiconductor device on which a blowing process is performed.

Referring to FIG. 2A, the fuse of the semiconductor device on which the blowing process is not performed includes an first interlayer insulating film 102, a conductive line 104 formed on the first interlayer insulating film 102, an first insulating film 106 planarized with the conductive line 104, an second interlayer insulating film 108 formed on the conductive line 104 and the first insulating film 106, a fuse contact 110 that penetrates the second interlayer insulating film 108 to be coupled to the conductive line 104, the plurality of contacts 112 that penetrates the second interlayer insulating film 108, the first insulating film 106 and the first interlayer insulating film 102 to be coupled to a substrate 100, the fuse pattern 114 coupled to the fuse contact 110 and the contact 112, and an second insulating film 116 planarized with the fuse pattern 114, and the interlayer insulating film 118 including the window 120 formed on the fuse pattern 114 and the second insulating film 116. The contact 112 is coupled to the middle portion of the fuse pattern 114 and formed in the same layer with the fuse contact 110 so that one end of the contact 112 is coupled to the fuse pattern 114. Although the other end of the contact 112 is coupled to the substrate 100 in the embodiment of the present invention, it is not limited thereto but the other end of the contact 112 can be coupled to any layer if one end of the contact 112 is just coupled to the fuse pattern 114. The fuse contact 110 includes one end coupled to the conductive line 104 and the other end coupled to the fuse pattern 114.

Referring to FIG. 2B, the fuse of the semiconductor device on which the blowing process is performed includes the first interlayer insulating film 102 formed on the substrate 100, the conductive line 104 formed on the first interlayer insulating film 102, the first insulating film 106 planarized with the conductive line 104, the second interlayer insulating film 108 formed on the conductive line 104 and the first insulating film 106, the fuse contact 110 that penetrates the second interlayer insulating film 108 to be coupled to the conductive line 104, the plurality of contacts 112 that penetrates the second interlayer insulating film 108, the first insulating film 106 and the first interlayer insulating film 102 and includes the recess 124 thereon, the fuse pattern 114 having the first portion and the second portion coupled to the fuse contact 110 and separated by the blowing region 122, the second insulating film 116 planarized with the fuse pattern 114, and the dielectric film 118 including the window 120 formed on the fuse pattern 114 and the second insulating film 116. The recess 124 is formed by partially removing an upper portion of the contact 112 using a laser applied to the fuse pattern 114. As a result, the cross-section after the blowing process is formed to have a three-dimensional structure by the recess 124. In a subsequent process for testing reliability, the three-dimensional structure prevents the movement of the fuse pattern 114, thereby preventing the generation of defects such as a short circuit.

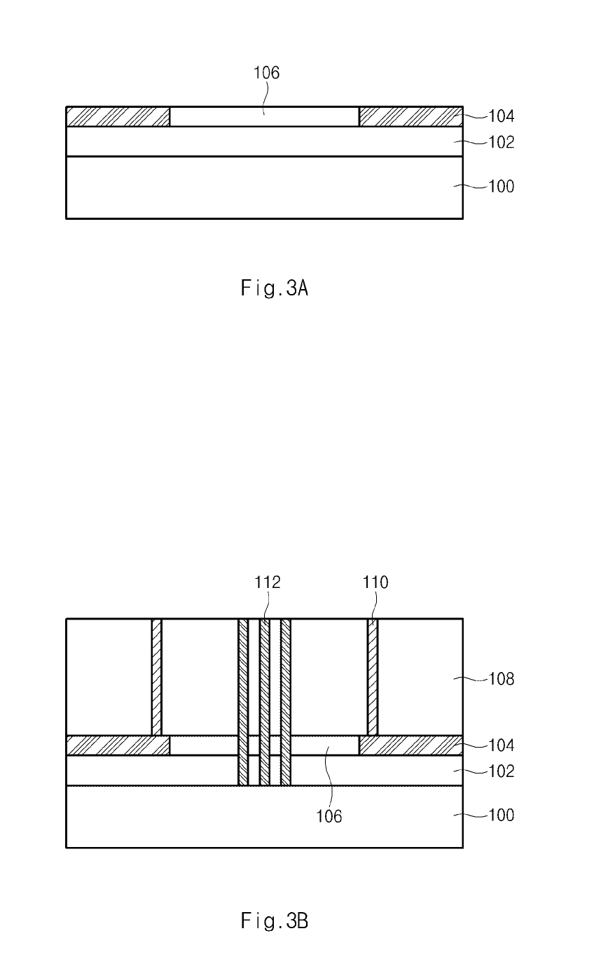

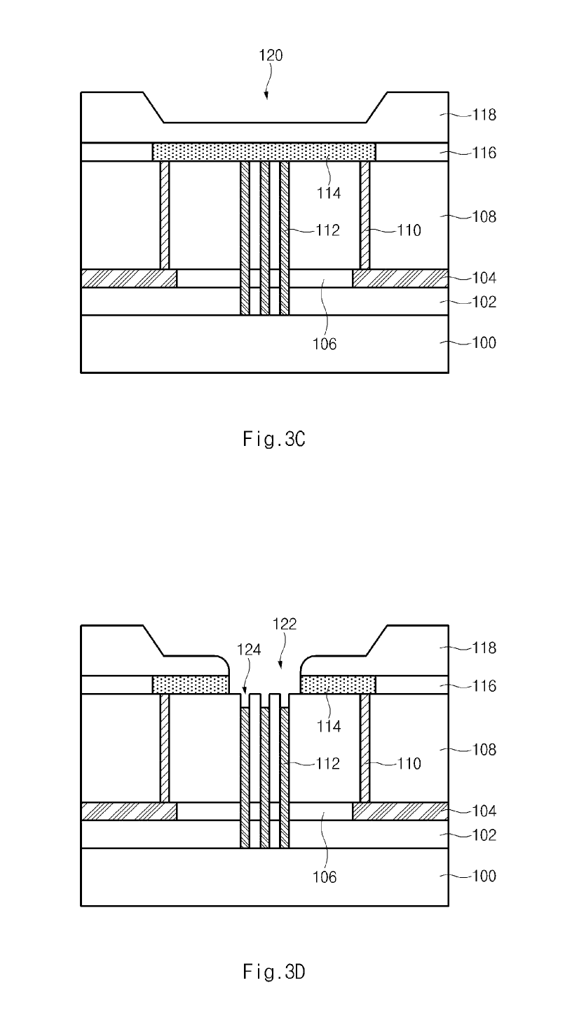

FIGS. 3A to 3D are cross-sectional views illustrating a method for forming the fuse of the semiconductor device in FIG. 1 according to an embodiment of the present invention.

Referring to FIG. 3A, the first interlayer insulating film 102 is formed on the substrate 100. After a conductive layer (not shown) is formed on the first interlayer insulating film 102, a photoresist pattern (not shown) is formed on the conductive layer (not shown). The conductive line layer (not shown) is etched using the photoresist pattern (not shown) as an etching mask to form the conductive line 104. Then, an interlayer insulating layer is formed to cover the conductive line 104. A planarizing process is performed on the interlayer insulating layer until the conductive line 104 is exposed, thereby forming the insulating film 106 planarized with the conductive line 104.

Referring to FIG. 3B, the interlayer insulating film 108 is formed on the first insulating film 106 and the conductive line 104. The second interlayer insulating film 108 is etched to expose the conductive line 104, thereby forming a fuse contact hole. The second interlayer insulating film 108, the first insulating film 106 and the first interlayer insulating film 102 are etched to expose the substrate 100, thereby forming a contact hole. Although the contact hole is formed to expose the substrate 100 in this embodiment, the contact hole may be coupled to any layer if the contact hole is coupled to the fuse pattern to be formed in a subsequent process. A conductive material is filled into the fuse contact hole to form the fuse contact 110. A conductive material is also filled into the contact hole to form the contact 112.

Referring to FIG. 3C, a fuse line layer is formed on the second interlayer insulating film 108, the fuse contact 110 and the contact 112. A photoresist pattern (not shown) is formed on the fuse line layer. The fuse line layer is etched using the photoresist pattern (not shown) as an etching mask to form the fuse pattern 114. Then, after an interlayer insulating layer is formed to cover the fuse pattern 114, a planarizing process is performed on the interlayer insulating layer until the fuse pattern 114 is exposed, thereby forming the second insulating film 116 planarized with the fuse pattern 114. The dielectric film 118 is formed on the fuse pattern 114 and the second insulating film 116. A certain portion of the dielectric film 118 is etched so that a given thickness of the dielectric film 118 remains on the fuse pattern 114, thereby forming the window 120 corresponding to the certain portion of the dielectric film 118.

Referring to FIG. 3D, a laser is applied to the fuse pattern 114 to partially remove the dielectric film 118 and the fuse pattern 114, thereby forming the blowing region 122. While the fuse pattern 114 is removed, the upper portion of the contact 112 disposed under the fuse pattern 114 is partially removed to form the recess 124 in a lower portion of the blowing region 122. That is, since the recess 124 is formed by the laser applied to the fuse pattern 114, it can be easily formed without an additional exposure process. The recess 124 prevents the movement of the fuse pattern 114 in the reliability test, e.g., highly accelerated temperature and humidity stress test (HAST), to be performed later, which prevents a short circuit.

As described above, in the method of forming the fuse of the semiconductor device according to the embodiment of the present invention, since the upper portion of the plurality of contacts coupled to the lower portion of the fuse pattern is partially etched during the blowing process performed in order to cut the fuse pattern, the recess is formed and thus it is possible to prevent the movement of the fuse pattern in the reliability test to be performed later.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or a non volatile memory device. Other additions, subtractions, or modifications are obvious in view of the present disclosure and are intended to fall within the scope of the appended claims.

What is claimed is:

1. A semiconductor device having a fuse, comprising:
a fuse pattern having a first portion and a second portion formed over an interlayer insulating film;
a blowing region separating the fuse pattern into the first portion and the second portion;
a plurality of contacts provided within contact holes below the blowing region; and
a recess formed by partially removing an upper portion of one or to more of the contacts within the contact holes.

2. The semiconductor device according to claim 1, further comprising:
a substrate provided below the interlayer insulating film and the contacts, wherein a lower end of each the contact contacts the substrate.

3. The semiconductor device according to claim 1, further comprising:
a substrate;
a first conductive line formed over the substrate and below the interlayer insulating film; and
a first fuse contact having an upper end and a lower end and extending through the interlayer insulating film, the upper end of the first fuse contact contacting the first portion of the fuse pattern, the lower end of the first fuse contact contacting the first conductive line.

4. The semiconductor device according to claim 3, further comprising:
a second conductive line formed over the substrate and below the interlayer insulating film, the second conductive line being separated from the first conductive line by an insulating layer; and
a second fuse contact having an upper end and a lower end and extending through the interlayer insulating film, the upper end of the second fuse contact contacting the second portion of the fuse pattern, the lower end of the second contact fuse contacting the second conductive line.

5. The semiconductor device according to claim 1, wherein the recess is configured to prevent the first and second portions of the fuse pattern from migrating to another location and causing a short circuit.

6. The semiconductor device according to claim 1, further comprising:
a substrate;
a first conductive line formed over the substrate and below the interlayer insulating film;
a second conductive line formed over the substrate and below the interlayer insulating film;
an insulating layer provided below the interlayer insulating film and separating the first conductive line from the second conductive line;
a first fuse contact having an upper end and a lower end and extending through the interlayer insulating film, the upper end of the first fuse contact contacting the first portion of the fuse pattern, the lower end of the first fuse contact contacting the first conductive line; and
a second fuse contact having an upper end and a lower end and extending through the interlayer insulating film, the upper end of the second fuse contact contacting the second portion of the fuse pattern, the lower end of the second contact fuse contacting the second conductive line.

7. A method of forming a semiconductor device having a fuse, the method comprising:
forming an interlayer insulating film over a substrate;
forming a plurality of contacts extending through the interlayer insulating film, each contact having an upper end and a lower end, the lower end contacting the substrate;
forming a fuse pattern over the interlayer insulating film and the contacts, the fuse pattern contacting the upper end of each contact;
removing a portion of the fuse pattern to form a blowing region and separating the fuse pattern into a first portion and a second portion; and
removing an upper portion of one or more of the contacts to form a recess.

8. The method according to claim 7, further comprising:
forming first and second conductive lines over the substrate;
etching the interlayer insulating film to form first and second fuse contact holes exposing the first and second conductive lines, respectively; and
filling the first and second fuse contact holes with conductive material to form first and second fuse contacts, respectively,
wherein the first fuse contact contacts the first conductive line and the second fuse contact contacts the second conductive line.

9. The method according to claim 8, wherein the first and second fuse contacts are separated from each other by an insulating layer formed between the interlayer insulating film and the substrate.

10. The method according to claim 8, wherein the fuse contact and the contacts are formed using the same material.

11. The method according to claim 7, wherein the contacts are formed to contact a middle portion of the fuse pattern.

12. The method according to claim 7, after forming the fuse pattern, further comprising:
forming a dielectric film over the fuse pattern; and
etching a portion of the dielectric film to reduce a thickness of the insulating film to thereon and define a window, whereby the dielectric film has a less thickness at the window than at an area adjacent to the window.

13. The method according to claim 12, wherein forming the blowing region comprises applying a laser to the window of the dielectric film and a portion of the fuse pattern underlying the window.

14. The method according to claim 7, wherein forming the recess comprises partially removing the upper portion of the contacts using the laser.
